(19) United States
(12) Patent Application Publication
(10) Pub. No.: US 2007/0280029 A1
(43) Pub. Date: Dec. 6, 2007

(54) CONNECTING SYSTEM BETWEEN DEVICES AND CONNECTING DEVICES

(75) Inventor: Takeshi YAMAMOTO, Osaka (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MegaChips Corporation, Osaka-shi (JP)

(21) Appl. No.: 11/754,536

(22) Filed: May 29, 2007

(30) Foreign Application Priority Data
Jun. 2, 2006 (JP) 2006-154453

(51) Int. Cl. G11C 8/00

(52) U.S. Cl. 365/230.05

(57) ABSTRACT

A first pin scramble buffer selectively connects first signal lines to first connecting terminals, and a second pin scramble buffer selectively connects second signal lines to second connecting terminals. The first connecting terminals and the second connecting terminals are connected in a fixed connection relationship. A parameter generator generates and updates a parameter indicative of a connection relationship. A first pin scramble controller controls the first pin scramble buffer to connect the first signal lines to the first connecting terminals in the connection relationship based on the parameter, and the second pin scramble controller controls the second pin scramble buffer to connect the second signal lines to the second connecting terminals in the connection relationship based on the parameter.

### BACKGROUND OF THE INVENTION

1. Field of the Invention

The present invention relates to connecting systems between devices and connecting devices, and more particularly to techniques of improving tamper resistance.

2. Description of the Background Art

It is easy for a third party to extract the contents of data and analyze the data with a measuring device and the like from a connecting terminal of devices connected with no security functions. To address this problem, signals exchanged between devices are generally encrypted to improve tamper resistance of the devices. Japanese Patent Application Laid-Open No. 2002-024090 discloses such technique of encrypting signals transmitted and received between devices.

Unfortunately, providing an encryption circuit increases the circuit size and costs. There is also a general desire for higher tamper resistance of devices.

### SUMMARY OF THE INVENTION

In a first aspect of a connecting system between devices according to the present invention, the connecting system includes: a first device, the first device including a plurality of first interconnects, a plurality of first connecting terminals, a first connecting section configured to electrically connect each of the first connecting terminals to at least one of the first interconnects in a variable first connection relationship based on at least one first parameter, and a first parameter generator configured to generate and update the first parameter; and a second device, the second device including a plurality of second interconnects, a plurality of second connecting terminals connected to the first connecting terminals in a fixed second connection relationship, and a second connecting section configured to electrically connect each of the second connecting terminals to at least one of the second interconnects in a variable third connection relationship correlating to the first connection relationship based on at least one second parameter. Preferably, the first parameter includes a plurality of parameters, and the first parameter generator includes a first table that stores the plurality of first parameters, and a first selecting section configured to generate and update first pointer information, the first pointer information designating one of the plurality of first parameters stored in the first table.

This makes it difficult to identify the respective functions of the first and second connecting terminals despite the fixed second connection relationship, thereby improving tamper resistance.

In a second aspect of the connecting system between devices according to the present invention, in the connecting system between devices according to the first aspect, the first parameter generator updates the first parameter in response to a request for a change in terminal arrangements issued from the second device.

This allows the second device to start changing terminal arrangements.

In a third aspect of the connecting system between devices according to the present invention, in the connecting system between devices according to the first aspect, the first parameter generator updates the first parameter in response to a request for a change in terminal arrangements issued from the first device.

This allows the first device to start changing terminal arrangements.

In a fourth aspect of the connecting system between devices according to the present invention, in the connecting system between devices according to any of the first to third aspects, the first table is fixed.

Therefore, the first device according to the first aspect can easily be made.

In a fifth aspect of the connecting system between devices according to the present invention, in the connecting system between devices according to any of the first to third aspects, the first table is updated.

Updating the first table that stores the first parameter makes it difficult to identify the first parameter based on the same first pointer information, thereby further improving the tamper resistance.

In a sixth aspect of the connecting system between devices according to the present invention, in the connecting system between devices according to any of the first to fifth aspects, the first pointer information is updated by the first selecting section to sequentially designate one of the plurality of first parameters stored in the first table.

Therefore, the first device according to the first aspect can easily be made.

In a seventh aspect of the connecting system between devices according to the present invention, in the connecting system between devices according to any of the first to fifth aspects, the first selecting section updates the first pointer information on a random basis.

Updating the first pointer information on a random basis makes it difficult to predict the first pointer information, thereby further improving the tamper resistance.

In an eighth aspect of the connecting system between devices according to the present invention, in the connecting system between devices according to any of the first to seventh aspects, the second parameter is the first parameter received from the first device.

As the first connecting section connects the first connecting terminals and first interconnects in the first connection relationship and the second connecting section connects the second connecting terminals and second interconnects in the third connection relationship using the same first parameter, the first connection relationship and the third connection relationship can easily be associated with each other.

In a ninth aspect of the connecting system between devices according to the present invention, in the connecting system between devices according to any of the first to seventh aspects, the second parameter includes a plurality of parameters, the second device further includes a second table that stores the plurality of second parameters, and the second connecting section selects one of the plurality of second parameters stored in the second table as a third parameter based on the first pointer information, and electrically connects each of the second connecting terminals to at least one of the second interconnects in the variable third connection relationship correlating to the first connection relationship based on the third parameter.

By generating and updating the first and second parameters in the first device and the second device, respectively, confidentiality of the first and second parameters is improved, thereby further improving the tamper resistance.

In a tenth aspect of the connecting system between devices according to the present invention, in the connecting system between devices according to any of the first to seventh aspects, the second parameter includes a plurality of parameters, the second device further includes a second parameter generator configured to generate and update the plurality of second parameters, the second parameter generator including a second table that stores the plurality of second parameters, and a second selecting section configured to generate and update second pointer information in synchronization with the first selecting section, the second pointer information designating one of the plurality of second parameters stored in the second table as a third parameter, and the second connecting section electrically connects each of the second connecting terminals to at least one of the second interconnects in the variable third connection relationship correlating to the first connection relationship based on the third parameter selected by the second parameter generator.

By generating and updating the first pointer information and first parameter, and the second pointer information and second parameter in the first device and the second device, respectively, confidentiality of the first and second pointer information and first and second parameters is improved, thereby further improving the tamper resistance.

In an eleventh aspect of the connecting system between devices according to the present invention, in the connecting system between devices according to the ninth or tenth aspect, the second table is fixed.

Therefore, the second device according to the ninth or tenth aspect can easily be made.

In a twelfth aspect of the connecting system between devices according to the present invention, in the connecting system between devices according to the ninth or tenth aspect, the second table is updated.

Updating the second table that stores the second parameter makes it difficult to identify the second parameter based on the same first or second pointer information, thereby further improving the tamper resistance.

In a thirteenth aspect of the connecting system between devices according to the present invention, in the connecting system between devices according to the tenth aspect, the second pointer information is updated by the second selecting section to sequentially designate one of the plurality of second parameters stored in the second table.

Therefore, the second device according to the tenth aspect can easily be made.

In a fourteenth aspect of the connecting system between devices according to the present invention, in the connecting system between devices according to the tenth aspect, the second selecting section updates the second pointer information on a random basis.

Updating the second pointer information on a random basis makes it difficult to predict the second pointer information, thereby further improving the tamper resistance.

In a first aspect of a connecting device according to the present invention, the connecting device includes: a plurality of interconnects; a plurality of connecting terminals; a connecting section configured to electrically connect each of the connecting terminals to at least one of the interconnects in a variable connection relationship based on at least one parameter; and a parameter generator configured to generate and update the parameter.

With this connecting device as the first device, the connecting system between devices according to the first aspect can be realized.

In a second aspect of the connecting device according to the present invention, in the connecting device according to the first aspect, the connecting section outputs the parameter to the exterior.

This allows the first parameter to be supplied to the second device according to the eighth aspect. Therefore, with this connecting device as the first device, the connecting system between devices according to the eighth aspect can be realized.

In a third aspect of the connecting device according to the present invention, in the connecting device according to the first aspect, the parameter includes a plurality of parameters, the parameter generator includes a table that stores the plurality of parameters, and a selecting section configured to generate and update pointer information, the pointer information designating one of the plurality of parameters stored in the table, and to select the parameter based on the pointer information, and the connecting section outputs the pointer information to the exterior.

This allows the first pointer information to be supplied to the second device according to the ninth aspect. Therefore, with this connecting device as the first device, the connecting system between devices according to the ninth aspect can be realized.

In a fourth aspect of the connecting device according to the present invention, in the connecting device according to the first aspect, the parameter generator generates and updates the parameter in synchronization with the exterior.

This allows the parameter generator to operate in synchronization with the second selecting section provided in the second device according to the tenth aspect. Therefore, with this connecting device as the first device, the connecting system between devices according to the tenth aspect can be realized.

In a fifth aspect of the connecting device according to the present invention, the connecting device includes: a plurality of interconnects; a plurality of connecting terminals; a connecting section electrically connects each of the connecting terminals to at least one of the interconnects in the variable connection relationship based on the parameter received from the exterior.

This allows the first parameter to be received from the first device according to the eighth aspect. Therefore, with this connecting device as the second device, the connecting system between devices according to the eighth aspect can be realized.

In a sixth aspect of the connecting device according to the present invention, in the connecting device according to the fifth aspect, the parameter includes a plurality of parameters, the connecting device further including a table that stores the plurality of parameters, and the connecting section selects one of the plurality of parameters stored in the table based on pointer information received from the exterior.

This allows the first pointer information to be received from the first device according to the ninth aspect. Therefore, with this connecting device as the second device, the connecting system between devices according to the ninth aspect can be realized.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 illustrates a schematic structural diagram of a system according to a first preferred embodiment of the present invention;

FIGS. 2 and 3 illustrate the internal structures of pin scramble buffers;

FIG. 4 shows a flowchart of an operation of changing terminal arrangements according to the first preferred embodiment;

FIG. 5 illustrates a schematic structural diagram of a system according to a second preferred embodiment of the present invention;

FIG. 6 shows a flowchart of an operation of changing terminal arrangements according to the second preferred embodiment;

FIG. 7 illustrates a schematic structural diagram of a system according to a third preferred embodiment of the present invention; and

FIG. 8 shows a flowchart of an operation of changing terminal arrangements according to the third preferred embodiment.

### DESCRIPTION OF THE PREFERRED EMBODIMENTS

Preferred embodiments of the present invention will be described with reference to the drawings. Like references indicate like or equivalent features or steps, and a discussion of those features or steps is not replicated.

### First Preferred Embodiment

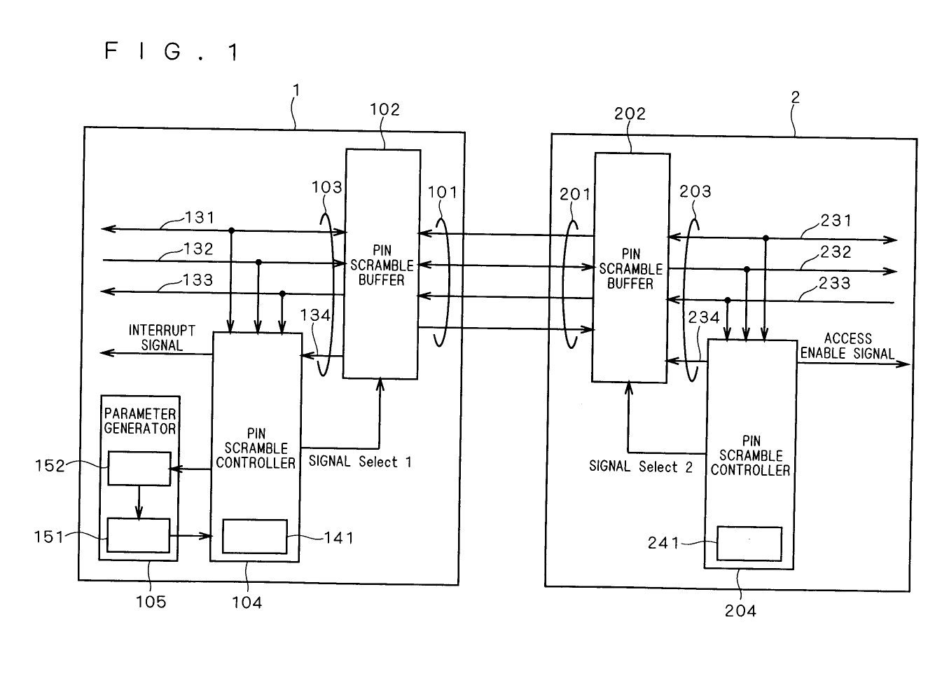

A connecting system between devices according to a first preferred embodiment of the invention is described. By way of example, FIG. 1 illustrates a schematic structural diagram of the connecting system. As shown, a system device 1 and a memory device 2 are electrically connected, and can communicate with each other.

Typically the system device 1 includes a CPU (not shown) or the like which instructs access to the memory device 2, and the memory device 2 includes a memory (not shown) which records data and a memory controller (not shown) or the like which accesses the memory. As these elements depart from the essentials of the invention, a discussion of these elements is omitted.

The system device 1 includes connecting terminals 101, a pin scramble buffer 102, signal lines 103 as interconnects, a pin scramble controller 104, and a parameter generator 105.

The signal lines 103 include signal lines 131 to 134 as shown in FIG. 1. By way of example, the signal line 131 is used for input and output, the signal line 132 for output, and the signal lines 133 and 134 for input.

The pin scramble buffer 102 electrically connects each of the connecting terminals 101 to at least one of the signal lines 103. The pin scramble controller 104 controls the pin scramble buffer 102, and causes the pin scramble buffer 102 to electrically connect the connecting terminals 101 and the signal lines 103 in a connection relationship based on a parameter generated and updated by the parameter generator 105. Namely, a section composed of the pin scramble buffer 102 and the pin scramble controller 104 may be regarded as a connecting section that electrically connects each of the connecting terminals 101 to at least one of the signal lines 103 in a variable connection relationship based on a parameter.

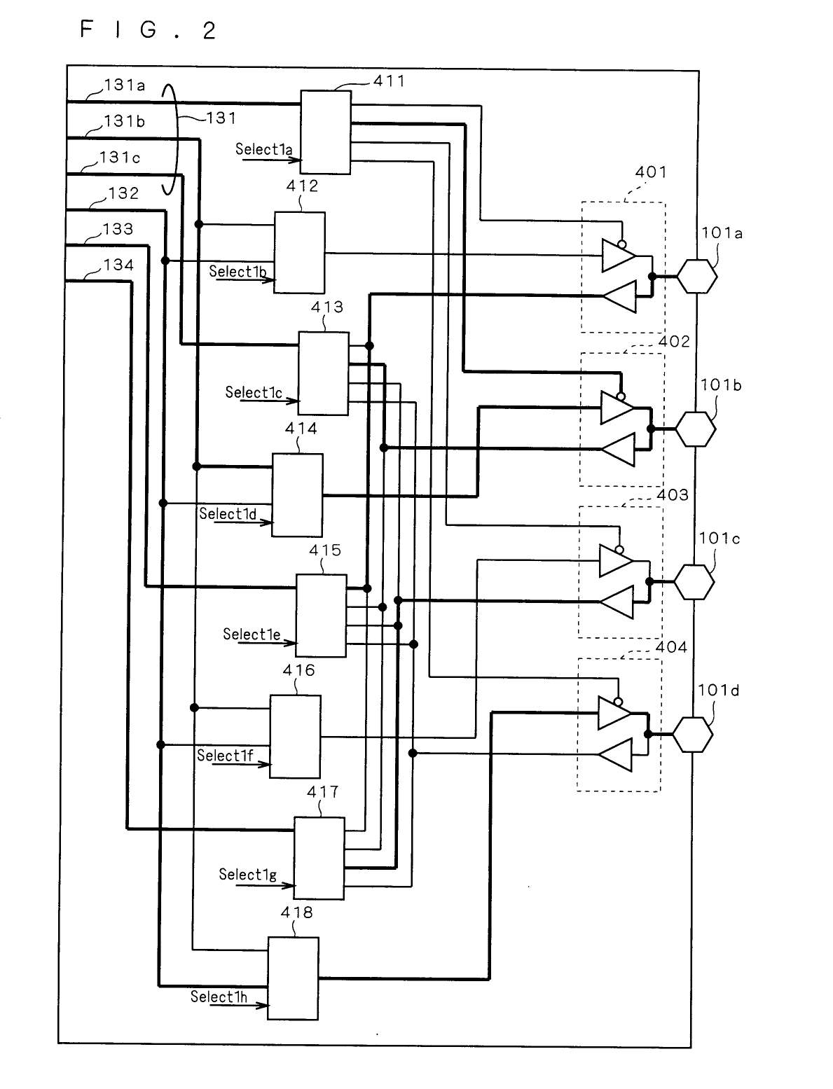

FIG. 2 illustrates the internal structure of the pin scramble buffer 102. The pin scramble buffer 102 includes buffers 401 to 404, and selectors 411 to 418. The buffers 401 to 404 each include a three-state output buffer and an input buffer. The selectors 411 to 418 receive signals (Select 1a to Select 1h) to be independently controlled by the pin scramble controller 104. Note that the signals Select 1a to Select 1h are indicated as a signal Select 1 in FIG. 1.

The signal line 131 for input and output includes an interconnect 131a connected to a control terminal of any of the three-state output buffers, an interconnect 131b connected to an input terminal of any of the three-state output buffers, and an interconnect 131c connected to an output terminal of any of the input buffers.

The selector 411 designates any of the buffers 401, 402, 403 and 404 for input and output. More specifically, the selector 411 connects the interconnect 131a to a control terminal of the three-state output buffer provided in any of the four buffers. Such selective connection is made by a selective operation in the selector 411 based on the signal Select 1a input to the selector 411.

The selector 413 connects the interconnect 131c to an output terminal of the input buffer provided in the buffer selected by the selector 411. Such selective connection is made by a selective operation in the selector 413 based on the signal Select 1c input to the selector 413.

In the FIG. 2 example, the interconnects 131a and 131c are connected to the same buffer 402 by the selectors 411 and 413, respectively.

The selectors 413, 415 and 417 connect the interconnect 131c, the signal lines 133 and 134 mutually exclusively to an output terminal of the input buffer provided in any of the buffers 401, 402, 403 and 404, respectively. Such exclusive connections are made by selective operations in the selectors 413, 415 and 417 based on the signals Select 1c, Select 1e and Select 1g input to the selectors 413, 415 and 417, respectively. Since the interconnect 131c is connected to the buffer that is determined by the selective operation of the selector 411 as mentioned above, the selectors 415 and 417 select buffers other than this selected buffer. In the FIG. 2 example, the signal lines 133 and 134 are connected to output terminals of the input buffers provided in the buffers 401 and 403, respectively.

The selectors 412, 414, 416 and 418 all connect the interconnect 131b and the signal line 132 mutually exclusively to an input terminal of the three-state output buffer provided in any of the buffers 401, 402, 403 and 404. Such exclusive connections are made by selective operations in the selectors 412, 414, 416 and 418 based on the signals Select 1b, Select 1d, Select 1f and Select 1h input to the selectors 412, 414, 416 and 418, respectively. Note that the interconnect 131b is connected to the buffer selected by the selectors 411 and 413. Thus in the FIG. 2 example where the interconnect 131b is connected to the buffer 402, the selector 414 corresponding to the buffer 402 selects the interconnect 131b, and connects the interconnect 131b to an input terminal of the three-state output buffer provided in the buffer 402. Also in FIG. 2, the signal line 132 is selected by the selector 418, to be connected to an input terminal of the three-state output buffer provided in the buffer 404 corresponding to the selector 418.

Because there are two interconnects as connection sources and four buffers as connection destinations, two of the selectors 412, 414, 416 and 418 do not need to establish connections between the interconnects and buffers. In FIG. 2, the selectors 412 and 416 do not contribute to the connections.

As a result of these connections, the interconnects 131b and 131c are connected to a terminal for input and output, the signal line 132 to a terminal for output, and the signal lines 133 and 134 to terminals for input, respectively. In the FIG. 2 example, a connecting terminal 101b acts as a terminal for input and output, a connecting terminal 101d as a terminal for output, and connecting terminals 101a and 101c as terminals for input, respectively. The connecting terminals 101a to 101d form the connecting terminals 101.

Referring back to FIG. 1, the parameter generator 105 generates and updates a parameter indicative of a connection relationship between the connecting terminals 101 and the signal lines 103. More specifically, the parameter generator 105 includes a table 151 and a counter circuit 152. The table 151 stores a plurality of parameters. The counter circuit 152 generates and updates a pointer signal designating a parameter in the table 151. The parameter generator 105 selects the parameter from the table 151 based on the pointer signal, thereby generating and updating the parameter. The counter circuit 152 may be regarded as a selecting section that generates and updates the pointer signal designating a parameter in the table 151. The counter circuit 152 counts a counter signal output from the pin scramble controller 104, and outputs the number as the pointer signal. Namely, the counter circuit 152 sequentially selects each of the plurality of parameters stored in the table 151.

The pin scramble controller 104 includes a register 141 therein. The pin scramble controller 104 receives the parameter generated and updated by the parameter generator 105 and stores the parameter in the register 141, to control the pin scramble buffer 102 based on the parameter. The pin scramble controller 104 can transmit an interrupt signal to the CPU (not shown) provided in the system device 1 to interrupt the operation of the CPU, and can also output the counter signal to the counter circuit 152.

The memory device 2 includes connecting terminals 201, a pin scramble buffer 202, signal lines 203 as interconnects, and a pin scramble controller 204. The signal lines 203 include signal lines 231 to 234, with the signal line 231 for input and output, the signal line 232 for input, and the signal lines 233 and 234 for output in a corresponding manner to the signal lines 103.

The pin scramble buffer 202 electrically connects each of the connecting terminals 201 to at least one of the signal lines 203. The pin scramble controller 204 controls the pin scramble buffer 202, and causes the pin scramble buffer 202 to electrically connect the connecting terminals 201 and the signal lines 203 in a connection relationship based on the parameter generated and updated by the parameter generator 105. Namely, a section composed of the pin scramble buffer 202 and the pin scramble controller 204 may be regarded as a connecting section that electrically connects each of the connecting terminals 201 to at least one of the signal lines 203 in a variable connection relationship based on a parameter.

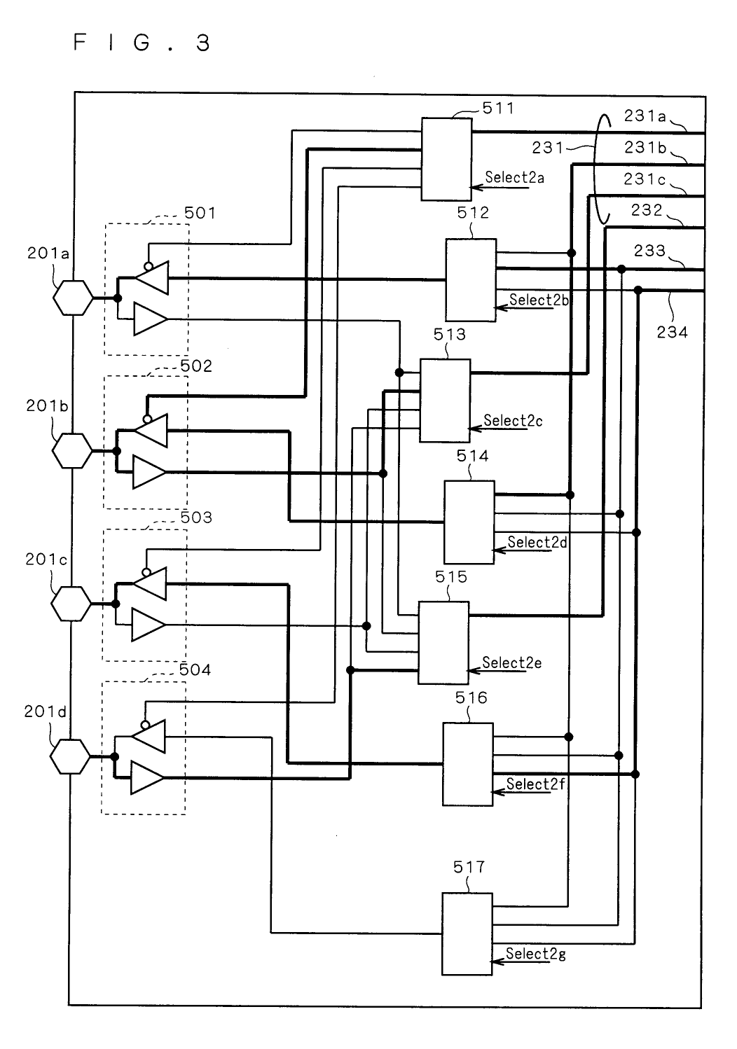

FIG. 3 illustrates the internal structure of the pin scramble buffer 202. Like the pin scramble buffer 102, the pin scramble buffer 202 includes buffers 501 to 504, and selectors 511 to 517. The buffers 501 to 504 each include a three-state output buffer and an input buffer. The selectors 511 to 517 receive signals (Select 2a to Select 2g) to be independently controlled by the pin scramble controller 204. Note that the signals Select 2a to Select 2g are indicated as a signal Select 2 in FIG. 1.

The signal line 231 for input and output includes an interconnect 231a connected to a control terminal of any of the three-state output buffers, an interconnect 231b connected to an input terminal of any of the three-state output buffers, and an interconnect 231c connected to an output terminal of any of the input buffers.

The selector 511 designates any of the buffers 501, 502, 503 and 504 for input and output. More specifically, the selector 511 connects the interconnect 231a to a control terminal of the three-state output buffer provided in any of the four buffers. Such selective connection is made by a selective operation in the selector 511 based on the signal Select 2a input to the selector 511.

The selector 513 connects the interconnect 231c to an output terminal of the input buffer provided in the buffer selected by the selector 511. Such selective connection is made by a selective operation in the selector 513 based on the signal Select 2c input to the selector 513.

In the FIG. 3 example, the interconnects 231a and 231c are connected to the same buffer 502 by the selectors 511 and 513, respectively.

The selectors 513 and 515 connect the interconnect 231c and the signal line 232 mutually exclusively to an output terminal of the input buffer provided in any of the buffers 501, 502, 503 and 504, respectively. Such exclusive connections are made by selective operations in the selectors 513 and 515 based on the signals Select 2c and Select 2e input to the selectors 513 and 515, respectively. Since the interconnect 231c is connected to the buffer that is determined by the selective operation of the selector 511 as mentioned above, the selector 515 selects a buffer other than this selected buffer. In the FIG. 3 example, the signals line 232 is connected to an output terminal of the input buffer provided in the buffer 504.

The selectors 512, 514, 516 and 517 all connect the interconnect 231b and the signal lines 233 and 234 mutually exclusively to an input terminal of the three-state output buffer provided in any of the buffers 501, 502, 503 and 504. Such exclusive connections are made by selective operations in the selectors 512, 514, 516 and 517 based on the signals Select 2b, Select 2d, Select 2f and Select 2g input to the selectors 512, 514, 516 and 517, respectively. Note that the interconnect 231b is connected to the buffer selected by the selectors 511 and 513. Thus in the FIG. 3 example where the interconnect 231b is connected to the buffer 502, the selector 514 corresponding to the buffer 502 selects the interconnect 231b, and connects the interconnect 231b to an input terminal of the three-state output buffer provided in the buffer 502. Also in FIG. 3, the signal line 233 is selected by the selector 512, to be connected to an input terminal of the three-state output buffer provided in the buffer 501 corresponding to the selector 512. Likewise, the signal line 234 is selected by the selector 516, to be connected to an input terminal of the three-state output buffer provided in the buffer 503 corresponding to the selector 516.

Because there are three interconnects as connection sources and four buffers as connection destinations, one of the selectors 512, 514, 516 and 517 does not need to establish connections between the interconnects and buffers. In FIG. 3, the selector 517 does not contribute to the connections.

As a result of these connections, the interconnects 231b and 231c are connected to a terminal for input and output, the signal line 232 to a terminal for input, and the signal lines 233 and 234 to terminals for output, respectively. In the FIG. 3 example, a connecting terminal 201b acts as a terminal for input and output, a connecting terminal 201d as a terminal for input, and connecting terminals 201a and 201c as terminals for output, respectively. The connecting terminals 201a to 201d form the connecting terminals 201.

The connecting terminals 201 are electrically connected to the connecting terminals 101 in a fixed connection relationship (where the connecting terminal 101a is connected the connecting terminal 201a, for example). According to the connection relationship indicated by heavy lines in FIGS. 2 and 3, the signal lines 131 and 231, the signal lines 132 and 232, the signal lines 133 and 233, and the signal lines 134 and 234 are connected to each other, respectively, through the connecting terminals 101 and 201. In the first preferred embodiment, the signal lines 103 and 203 are connected in a fixed manner by this connection relationship.

Referring back to FIG. 1, the pin scramble controller 204 includes a register 241 therein. The pin scramble controller 204 receives the parameter generated and updated by the parameter generator 105 in a manner described later and stores the parameter in the register 241, to control the pin scramble buffer 202 based on the parameter. To fix the connection relationship between the signal lines 103 and 203 mentioned in the previous paragraph, the pin scramble buffer 202 controls a connection relationship between the signal lines 203 and the connecting terminals 201 in a corresponding manner to the connection relationship between the signal lines 103 and the connecting terminals 101. The pin scramble buffer 202 can also output an access enable signal to the memory controller (not shown) provided in the memory device 2 to enable/disable access to the memory (not shown) provided in the memory device 2.

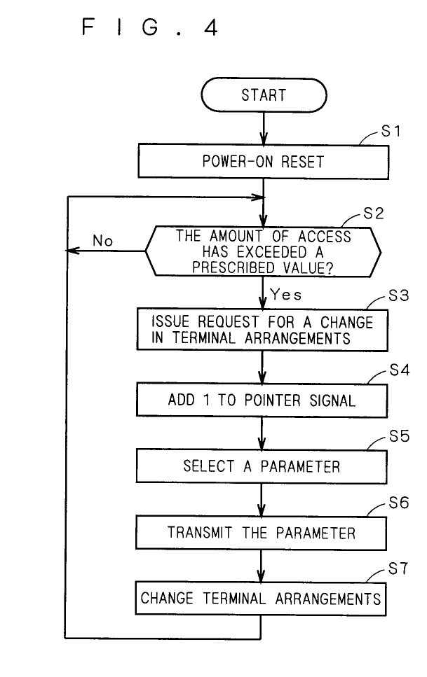

FIG. 4 shows an operation of changing terminal arrangements in this system. Changing terminal arrangements means changing the connection relationship between the connecting terminals 101 and the signal lines 103 and the connection relationship between the connecting terminals 201 and the signal lines 203 in a corresponding manner. First in step S1, terminal arrangements are initialized with power-on reset. More specifically, the pin scramble controllers 104 and 204 initialize the registers 141 and 241 therein, respectively. With the initialization, parameters stored in the registers 141 and 241 are defined as a unique value (initial parameters). The pin scramble controllers 104 and 204 control the pin scramble buffers 102 and 202 based on the initial parameters stored in the registers 141 and 241, respectively, to initialize terminal arrangements. The initial connection relationships are indicated by the heavy lines in FIGS. 2 and 3.

In step S2, the pin scramble controller 204 connected to the signal lines 231 to 233 detects the amount of data access to the memory provided in the memory device 2, to determine whether the amount of data access exceeds a prescribed value. When the amount of data access does not exceed the prescribed value, step S2 is executed again.

When the amount of data access exceeds the prescribed value, processing goes to step S3. In step S3, the pin scramble controller 204 issues a request for a change in terminal arrangements to the system device 1 through the signal line 234, the connecting terminal 201c, the connecting terminal 101c, and the signal line 134 in this order, while lowering the potential (to L) of the access enable signal and inputting the signal to the memory controller (not shown), thus disabling access to the memory (not shown) provided in the memory device 2. Upon receipt of the request for a change in terminal arrangements, the pin scramble controller 104 outputs an interrupt signal to the CPU (not shown) provided in the system device 1 to interrupt the operation of the CPU. This prevents malfunction resulting from access to the memory device 2 during the operation of changing the terminal arrangements.

In step S4, the pin scramble controller 104 having received the request for a change in terminal arrangements through the signal line 134 outputs a counter signal to the counter circuit 152. The counter circuit 152 counts counter signals previously input thereto, and outputs the number as a pointer signal. Namely, one is added to the pointer signal each time step S4 is executed (each time the operation of changing terminal arrangements is performed).

In step S5, the parameter generator 105 selects a parameter in the table 151 based on the pointer signal. Each of the parameters is sequentially selected from the table 151 each time the pointer signal is updated. Then the parameter generator 105 outputs the generated parameter to the pin scramble controller 104.

In step S6, the pin scramble controller 104 having received the parameter transmits the parameter to the pin scramble controller 204 through the signal line 131, the connecting terminal 101b, the connecting terminal 201b, and the signal line 231 in this order, while storing the parameter in the register 141. Upon receipt of the parameter, the pin scramble controller 204 also stores the parameter in the register 241.

In step S7, the pin scramble controllers 104 and 204 temporarily release the connecting terminals 101 and 201 by the signals Select 1 and Select 2 (raise the control terminals of the buffers 401 to 404 and 501 to 504 to “H”), respectively. Then the pin scramble controllers 104 and 204 control the pin scramble buffers 102 and 202 based on the parameters stored in the registers 141 and 241, respectively, to change the terminal arrangements.

After the terminal arrangements have been changed, the pin scramble controller 104 informs the CPU provided in the system device 1 of the termination of the interrupt process, to release the interruption of the CPU operation. On the other hand, the pin scramble controller 204 raises the potential (to H) of the access enable signal to enable access to the memory provided in the memory device 2.

Processing then returns to step S2. When the amount of data access after the change in terminal arrangements exceeds the prescribed value again, the terminal arrangements are changed again. In such ways, the terminal arrangements are changed each time the amount of data access to the memory device 2 exceeds the prescribed value. The result is that it is difficult for a third party to identify the functions (difference among input, output, and input and output) of the connecting terminals 101 and 201, thereby improving tamper resistance of the system device 1 and memory device 2.

Although the pin scramble controller 204 detects the amount of data access and issues a request for a change in terminal arrangements to the system device 1 in the first preferred embodiment, the pin scramble controller 104 connected to the signal lines 131 to 133 may detect the amount of data access and issue a request for a change in terminal arrangements to the memory device 2.

Further, although the amount of data access is used as a criterion to determine whether to change the terminal arrangements, the criterion may be a change in contents of a command transmitted from the system device 1 to the memory device 2, or a change in address area of the command.

The parameter generated by the parameter generator 105 and transmitted to the pin scramble controller 204 in the first preferred embodiment may be transmitted after being encrypted on the side of the system device 1 and decrypted on the side of the memory device 2. This provides further improved tamper resistance.

The table 151 provided in the parameter generator 105 may be a fixed table, or a changeable table. The tamper resistance will be further improved if the table 151 is updated with time. Also, a scramble circuit may be provided instead of the counter circuit 152. This allows the pointer signal designating a parameter in the table 151 to be generated on a random basis, thereby further improving the tamper resistance. By way of example, a scramble circuit for generating PN (Pseudo Noise) may be employed as the scramble circuit. In such instance, the scramble circuit receives only the initial value during the first operation of changing the terminal arrangements, and clock signals thereafter.

Furthermore, the parameter generator 105 may be provided in the memory device 2 instead of being provided in the system device 1. In such instance, the memory device 2 generates and transmits a parameter to the system device 1.

### Second Preferred Embodiment

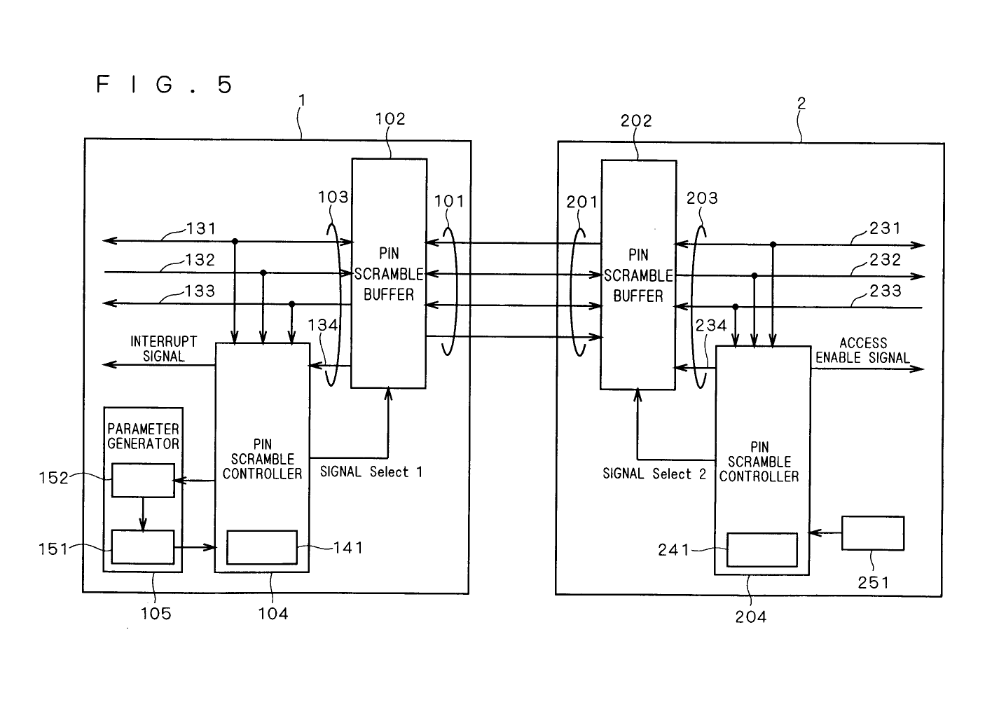

A connecting system between devices according to a second preferred embodiment of the invention is described. By way of example, FIG. 5 illustrates a schematic structural diagram of the connecting system. The difference between this system and the system according to the first preferred embodiment is that the memory device 2 includes a table 251 identical to the table 151.

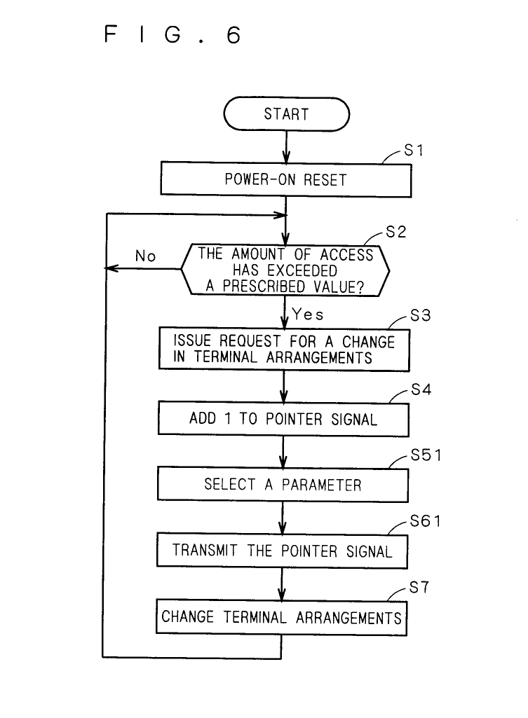

FIG. 6 shows an operation of changing terminal arrangements in this system. The operation of changing terminal arrangements according to the second preferred embodiment will be described by explaining the operational difference from the first preferred embodiment.

In step S51 after steps S1 to S4, the parameter generator 105 selects a parameter in the table 151 based on the pointer signal. Each of the parameters is sequentially selected from the table 151 each time the pointer signal is updated. Then the parameter generator 105 outputs the generated pointer signal and parameter to the pin scramble controller 104.

In step S61, the pin scramble controller 104 having received the pointer signal and parameter transmits the pointer signal to the pin scramble controller 204 through the signal line 131, the connecting terminal 101b, the connecting terminal 201b, and the signal line 231 in this order, while storing the parameter in the register 141. Upon receipt of the pointer signal, the pin scramble controller 204 selects a parameter from the table 251 based on the pointer signal, and stores the parameter in the register 241. At this moment, identical parameters are stored in the registers 141 and 241 provided in the pin scramble controllers 104 and 204, respectively.

In step S7, the pin scramble controllers 104 and 204 release the connecting terminals 101 and 201, respectively, and then control the pin scramble buffers 102 and 202 based on the parameters stored in the registers 141 and 241, respectively, to change the terminal arrangements.

It is therefore unnecessary to transmit and receive parameters themselves indicative of connection relationships between the system device 1 and the memory device 2. This improves confidentiality of parameters and further improves the tamper resistance of the system device 1 and the memory device 2.

Although described as being identical, the tables 251 and 151 may be different from each other. When the contents of the table 251 are different from those of the table 151, the pin scramble controllers 104 and 204 control the pin scramble buffers 102 and 202, respectively, in consideration of the correlation between the tables 151 and 251. It should be appreciated that all the alternatives to this system, such as those mentioned in the first preferred embodiment, can of course be applied to the second preferred embodiment.

### Third Preferred Embodiment

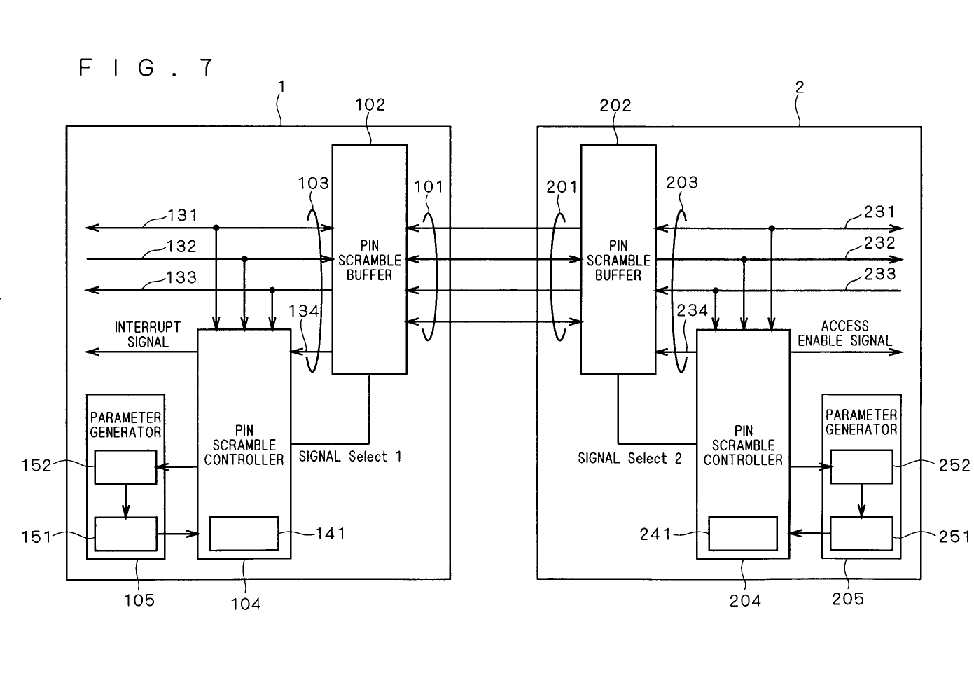

A connecting system between devices according to a third preferred embodiment of the invention is described. By way of example, FIG. 7 illustrates a schematic structural diagram of the connecting system. The difference between this system and the system according to the first preferred embodiment is that the memory device 2 includes a parameter generator 205.

The parameter generator 205 includes the table 251 and a counter circuit 252. The table 251 and the counter circuit 252 are identical to the table 151 and the counter circuit 152, respectively. Note that while the counter circuit 152 counts a counter signal from the pin scramble controller 104, the counter circuit 252 counts a counter signal from the pin scramble controller 204.

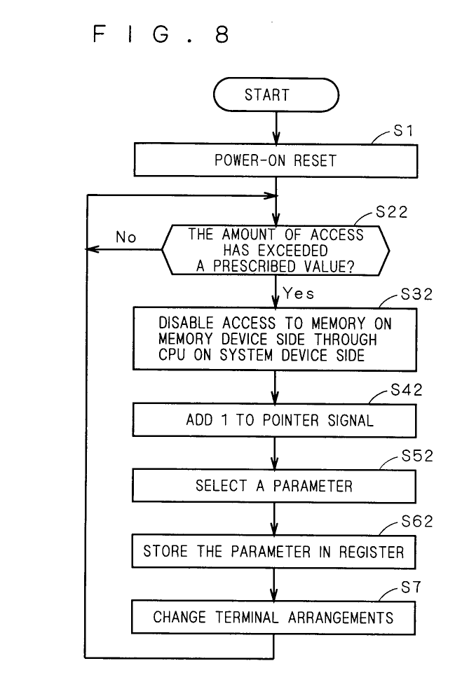

FIG. 8 shows an operation of changing terminal arrangements in this system. The operation of changing terminal arrangements according to the third preferred embodiment will be described by explaining the operational difference from the first preferred embodiment.

In step S22, the pin scramble controllers 104 and 204 each detect the amount of data access to the memory provided in the memory device 2, to determine whether the amount of data access exceeds a prescribed value. When the amount of data access does not exceed the prescribe value, step S22 is executed again.

When the amount of data access exceeds the prescribed value, processing goes to step S32. In step S32, the pin scramble controller 104 outputs an interrupt signal to the CPU (not shown) provided in the system device 1 to interrupt the operation of the CPU. Meanwhile, the pin scramble controller 204 lowers the potential (to L) of the access enable signal and inputs the signal to the memory controller (not shown), thus disabling access to the memory (not shown) provided in the memory device 2. This prevents malfunction resulting from access to the memory device 2 during the operation of changing the terminal arrangements.

In step S42, the pin scramble controllers 104 and 204 output counter signals to the counter circuits 152 and 252, respectively. The counter circuits 152 and 252 count the synchronizingly received counter signals and output the number as pointer signals, respectively. Namely, one is added to the pointer signals output from the counter circuits 152 and 252, respectively, each time step S42 is executed (each time the operation of changing terminal arrangements is performed). The counter circuits 152 and 252 thus output pointer signals indicative of the same value.

In step S52, the parameter generators 105 and 205 select parameters from the tables 151 and 251 based on their respectively generated pointer signals, respectively. Being selected from the identical tables 151 and 251 based on the identical pointer signals, the parameters generated by the parameter generators 105 and 205 are also identical to each other. Each of the parameters is sequentially selected from the tables 151 and 251, respectively, each time the pointer signals are updated. Then the parameter generators 105 and 205 output their respectively generated parameters to the pin scramble controllers 104 and 204, respectively.

In step S62, the pin scramble controllers 104 and 204 having received their respective parameters store the parameters in the registers 141 and 241, respectively.

In step S7, the pin scramble controllers 104 and 204 temporarily release the connecting terminals 101 and 201 by the signals Select 1 and Select 2 (raise the control terminals of the buffers 401 to 404 and 501 to 504 to “H”), respectively, and then control the pin scramble buffers 102 and 202 based on the parameters stored in the registers 141 and 241, respectively, to change the terminal arrangements.

It is therefore unnecessary to transmit and receive a pointer signal and parameters between the system device 1 and the memory device 2. This improves confidentiality of the pointer signal and parameters, and further improves the tamper resistance of the system device 1 and the memory device 2.

Identical scramble circuits may be provided instead of the counter circuits 152 and 252 in the parameter generators 105 and 205, respectively. When employing scramble circuits for generating PN, for example, the scramble circuits receive identical initial values and identical clock signals thereafter, to operate in synchronization with each other.

Although described as being identical as in the second preferred embodiment, the tables 251 and 151 may be different from each other. Further, although described as being identical, the counter circuits 152 and 252 may output different pointer signals. In such instance, the pin scramble controllers 104 and 204 control the pin scramble buffers 102 and 202, respectively, in consideration of the correlation between the pointer signals and tables.

Moreover, although a request for a change in terminal arrangements is not issued because the pin scramble controllers 104 and 204 each detect the amount of data access to the memory provided in the memory device 2, one of the pin scramble controllers 104 and 204 may detect the amount of data access and issue a request for a change in terminal arrangements to the other pin scramble controller.

It should be appreciated that all the alternatives to this system, such as those mentioned in the first preferred embodiment, can of course be applied to the third preferred embodiment.

While the invention has been shown and described in detail, the foregoing description is in all aspects illustrative and not restrictive. It is therefore understood that numerous modifications and variations can be devised without departing from the scope of the invention.

What is claimed is:

1. A connecting system between devices, comprising:
a first device, said first device comprising
a plurality of first interconnects,
a plurality of first connecting terminals,
a first connecting section configured to electrically connect each of said first connecting terminals to at least one of said first interconnects in a variable first connection relationship based on at least one first parameter, and
a first parameter generator configured to generate and update said first parameter; and
a second device, said second device comprising
a plurality of second interconnects,
a plurality of second connecting terminals connected to said first connecting terminals in a fixed second connection relationship, and
a second connecting section configured to electrically connect each of said second connecting terminals to at least one of said second interconnects in a variable third connection relationship correlating to said first connection relationship based on at least one second parameter.

2. The connecting system between devices according to claim 1, wherein said first parameter generator updates said first parameter in response to a request for a change in terminal arrangements issued from said second device.

3. The connecting system between devices according to claim 1, wherein said first parameter generator updates said first parameter in response to a request for a change in terminal arrangements issued from said first device.

4. The connecting system between devices according to claim 1, wherein
said first parameter includes a plurality of parameters, and
said first parameter generator comprises a first table that stores said plurality of first parameters, and a first selecting section configured to generate and update first pointer information, said first pointer information designating one of said plurality of first parameters stored in said first table.

5. The connecting system between devices according to claim 4, wherein said first table is fixed.

6. The connecting system between devices according to claim 4, wherein said first table is updated.

7. The connecting system between devices according to claim 4, wherein said first pointer information is updated by said first selecting section to sequentially designate one of said plurality of first parameters stored in said first table.

8. The connecting system between devices according to claim 4, wherein said first selecting section updates said first pointer information on a random basis.

9. The connecting system between devices according to claim 1, wherein said second parameter is said first parameter received from said first device.

10. The connecting system between devices according to claim 4, wherein
said second parameter includes a plurality of parameters,
said second device further comprises a second table that stores said plurality of second parameters, and
said second connecting section selects one of said plurality of second parameters stored in said second table as a third parameter based on said first pointer information, and electrically connects each of said second connecting terminals to at least one of said second interconnects in said variable third connection relationship correlating to said first connection relationship based on said third parameter.

11. The connecting system between devices according to claim 4, wherein
said second parameter includes a plurality of parameters,
said second device further comprises a second parameter generator configured to generate and update said plurality of second parameters, said second parameter generator comprising a second table that stores said plurality of second parameters, and a second selecting section configured to generate and update second pointer information in synchronization with said first selecting section, said second pointer information designating one of said plurality of second parameters stored in said second table as a third parameter, and
said second connecting section electrically connects each of said second connecting terminals to at least one of said second interconnects in said variable third connection relationship correlating to said first connection relationship based on said third parameter selected by said second parameter generator.

12. The connecting system between devices according to claim 10, wherein said second table is fixed.

13. The connecting system between devices according to claim 11, wherein said second table is fixed.

14. The connecting system between devices according to claim 10, wherein said second table is updated.

15. The connecting system between devices according to claim 11, wherein said second table is updated.

16. The connecting system between devices according to claim 11, wherein said second pointer information is updated by said second selecting section to sequentially designate one of said plurality of second parameters stored in said second table.

17. The connecting system between devices according to claim 11, wherein said second selecting section updates said second pointer information on a random basis.

18. A connecting device comprising:
a plurality of interconnects;
a plurality of connecting terminals;
a connecting section configured to electrically connect each of said connecting terminals to at least one of said interconnects in a variable connection relationship based on at least one parameter; and
a parameter generator configured to generate and update said parameter.

19. The connecting device according to claim 18, wherein said connecting section outputs said parameter to the exterior.

20. The connecting device according to claim 18, wherein
said parameter includes a plurality of parameters,
said parameter generator comprises a table that stores said plurality of parameters, and a selecting section configured to generate and update pointer information, said pointer information designating one of said plurality of parameters stored in said table, and to select said parameter based on said pointer information, and
said connecting section outputs said pointer information to the exterior.

21. The connecting device according to claim 18, wherein said parameter generator generates and updates said parameter in synchronization with the exterior.

22. A connecting device comprising:
a plurality of interconnects;
a plurality of connecting terminals;
a connecting section configured to electrically connect each of said connecting terminals to at least one of said interconnects in a variable connection relationship based on at least one parameter received from the exterior.

23. The connecting device according to claim 22, wherein
said parameter includes a plurality of parameters,
said connecting device further comprising a table that stores said plurality of parameters,
and further wherein said connecting section selects one of said plurality of parameters stored in said table based on pointer information received from the exterior.
